(19) United States
(12) Patent Application Publication
(10) Pub. No.: US 2016/0002820 A1
(43) Pub. Date: Jan. 7, 2016

(54) CRUCIBLE AND METHOD FOR PRODUCING SINGLE CRYSTAL

(71) Applicant: SUMITOMO ELECTRIC INDUSTRIES, LTD., Osaka-shi (JP)

(72) Inventors: Tsutomu HORI, Itami-shi (JP); Shunsaku UETA, Itami-shi (JP); Akira MATSUSHIMA, Itami-shi (JP)

(21) Appl. No.: 14/789,079

(22) Filed: Jul. 1, 2015

(30) Foreign Application Priority Data
Jul. 4, 2014 (JP) 2014-139148
Jul. 4, 2014 (JP) 2014-139149
Jul. 4, 2014 (JP) 2014-139150

(51) Int. Cl. C30B 23/06; F27B 14/10; C30B 29/36

(52) U.S. Cl. CPC C30B 23/066; C30B 29/36; F27B 14/10; F27B 2014/102; F27B 2014/104

(57) ABSTRACT

A crucible has a bottom and a cylindrical side surface. In the crucible, a source material is sublimated to grow a single crystal. The crucible includes a third region configured to receive a source material, a second region extending from the third region in a direction away from the bottom, and a first region extending from the second region in a direction away from the bottom. The crucible includes a first wall and a second wall inside the side surface. The first wall surrounds the first region, the second wall surrounds the second region. The crucible includes a first chamber between the first wall and the side surface and a second chamber between the second wall and the side surface. The distance between horizontal opposite portions on the first wall is constant or increases as the horizontal opposite portions approach the bottom.

### BACKGROUND OF THE INVENTION

1. Field of the Invention

The present disclosure relates to a crucible and a method for producing a single crystal.

2. Description of the Related Art

A single crystal, such as a silicon carbide single crystal, can be produced by a sublimation method, by which a source material is sublimated and recrystallizes on a seed crystal in a crucible. See Japanese Unexamined Patent Application Publication No. 2005-225710, U.S. Pat. No. 5,683,507, and Japanese Unexamined Patent Application Publication Nos. 2008-074662, 2013-166672, 2004-352590, 2010-248039, 2010-275190, 2007-077017, and 2005-053739, for example.

### SUMMARY OF THE INVENTION

A crucible according to the present disclosure has a bottom and a cylindrical side surface. In the crucible, a source material is sublimated to grow a single crystal. The crucible includes a third region configured to receive a source material, a second region extending from the third region in a direction away from the bottom, and a first region extending from the second region in a direction away from the bottom. The crucible includes a first wall and a second wall inside the side surface. The first wall surrounds the first region, and the second wall surrounds the second region. The crucible includes a first chamber between the first wall and the side surface and a second chamber between the second wall and the side surface. The distance between horizontal opposite portions on the first wall is constant or increases as the horizontal opposite portions approach the bottom. The distance between horizontal opposite portions on the second wall increases as the horizontal opposite portions approach the bottom. The inclination angle α of the first wall with respect to the direction perpendicular to the bottom is smaller than the inclination angle β of the second wall with respect to the direction perpendicular to the bottom. The inclination angle α is 30 degrees or less. The inclination angle β is 70 degrees or less. The difference between the inclination angle β and the inclination angle α is 50 degrees or less. The first chamber includes a heat insulator. The second chamber is empty.

### BRIEF DESCRIPTION OF THE DRAWINGS

FIG. 1 is a schematic cross-sectional view of the structure of a crucible main body.

FIG. 2 is a schematic cross-sectional view of the structure of a crucible.

FIG. 3 is a flow chart of a method for producing a single crystal.

FIG. 4 is a schematic cross-sectional view of a single crystal production process.

FIG. 5 is a schematic cross-sectional view of another single crystal production process.

FIG. 6 is a schematic cross-sectional view of the structure of a crucible according to a first modified example.

FIG. 7 is a schematic cross-sectional view of the structure of a crucible according to a second modified example.

FIG. 8 is a graph showing the relationship between the inclination angle β and the growth rate.

### DESCRIPTION OF THE PREFERRED EMBODIMENTS

First, the embodiments of the present disclosure will be described below.

A crucible according to an embodiment of the present disclosure has a bottom and a cylindrical side surface. In the crucible, a source material is sublimated to grow a single crystal. The crucible includes a third region configured to receive a source material, a second region extending from the third region in a direction away from the bottom, and a first region extending from the second region in a direction away from the bottom. The crucible includes a first wall and a second wall inside the side surface. The first wall surrounds the first region, and the second wall surrounds the second region. The crucible includes a first chamber between the first wall and the side surface and a second chamber between the second wall and the side surface. The distance between horizontal opposite portions on the first wall is constant or increases as the horizontal opposite portions approach the bottom. The distance between horizontal opposite portions on the second wall increases as the horizontal opposite portions approach the bottom. The inclination angle α of the first wall with respect to the direction perpendicular to the bottom is smaller than the inclination angle β of the second wall with respect to the direction perpendicular to the bottom. The inclination angle α is 30 degrees or less. The inclination angle β is 70 degrees or less. The difference between the inclination angle β and the inclination angle α is 50 degrees or less. The first chamber includes a heat insulator. The second chamber is empty.

In a crucible for use in the production of a single crystal by a sublimation method, the cross-sectional area of an interior space in the direction perpendicular to the single crystal growth direction is preferably greater in a region for holding a source material than in a region for holding a seed crystal. This is because the growth efficiency can be improved by collecting a gas generated by sublimation of a source material and supplying the collected gas to a seed crystal. Even with such a structure, however, the following problem may occur in a step for growing a single crystal on a seed crystal.

First, crystalline mass in contact with a source material in the vicinity of a central portion of an interior space of a crucible (a region separated from a wall portion surrounding the interior space of the crucible) may be formed by recrystallization. The crystalline mass retards sublimation of the source material. This decreases the amount of gas supplied per unit time, that is, the gas supply rate to a seed crystal. This sometimes results in a low single crystal growth rate.

Furthermore, the quality of a single crystal may be lowered by many defects.

In a crucible according to the present disclosure, the first chamber includes a heat insulator. The heat insulator decreases the thermal conductivity of the first chamber. Radiation has a great influence in a temperature range up to 2000° C., for example. The heat insulator in the first chamber can block radiation. The heat insulator reduces heat transfer in the first chamber. Thus, the heat insulator reduces the effects of radiant heat from the first chamber to the first region. This reduces the temperature difference in a direction perpendicular to the crystal growth direction in the first region. This reduces the difference in thickness between a radial end portion and a central portion of a single crystal during single crystal growth. This reduces strain in the single crystal. Thus, the single crystal has a decreased number of defects resulting from strain.

In a crucible according to the present disclosure, the second chamber is empty. Radiation has a great influence in a temperature range up to 2000° C., for example. The empty second chamber does not block radiation. Thus, heat is easily transferred in the second chamber. This increases radiant heat from the second wall portion to a source material in the vicinity of the central portion of the interior space of the crucible. This suppresses a decrease in temperature in the vicinity of the central portion and suppresses the formation of crystalline mass in the vicinity of the central portion. This suppresses a decrease in single crystal growth rate.

Thus, the decrease in growth rate can be suppressed in a crucible according to an embodiment of the present disclosure, and the number of defects in the resulting single crystal can be decreased.

The inclination angle α of the crucible may be 5 degrees or less. The inclination angle β of the crucible may be 20 degrees or more. The inclination angle β of the crucible may be 50 degrees or less.

In the crucible, the first chamber may include a single heat insulator. In the crucible, the first chamber may include radially stacked heat insulators. In the crucible, the first chamber may include heat insulators stacked in the direction perpendicular to the bottom.

The crucible may further include a lid portion for covering an opening of the crucible. The lid portion may have a holding portion for holding a seed crystal on a surface thereof facing the bottom.

A crucible according to another embodiment of the present disclosure has a bottom and a cylindrical side surface. In the crucible, a source material is sublimated to grow a single crystal. The crucible includes a third region configured to receive a source material, a second region extending from the third region in a direction away from the bottom, and a first region extending from the second region in a direction away from the bottom. The crucible includes a first wall and a second wall inside the side surface. The first wall surrounds the first region, and the second wall surrounds the second region. The crucible includes a first chamber between the first wall and the side surface and a second chamber between the second wall and the side surface. The distance between horizontal opposite portions on the first wall is constant or increases as the horizontal opposite portions approach the bottom. The distance between horizontal opposite portions on the second wall increases as the horizontal opposite portions approach the bottom. The inclination angle α of the first wall with respect to the direction perpendicular to the bottom is 5 degrees or less. The inclination angle β of the second wall with respect to the direction perpendicular to the bottom ranges from 20 to 50 degrees. The first chamber includes radially stacked heat insulators. The second chamber is empty.

The crucible is used in a method for producing a single crystal according to an embodiment of the present disclosure. The production method includes placing a source material in at least part of the third region, placing a seed crystal on the holding portion, sublimating the source material to grow the single crystal on the seed crystal, and separating the single crystal from the seed crystal. A method for producing a single crystal according to an embodiment of the present disclosure can produce a single crystal having a decreased number of defects while suppressing a decrease in growth rate.

In the method for producing a single crystal, the placing of a seed crystal on the holding portion may include placing the seed crystal in the first region. The sublimating of the source material to grow the single crystal on the seed crystal may include limiting the single crystal growth in the first region. A single crystal having a decreased number of defects can be produced.

In the method for producing a single crystal, the seed crystal may be a silicon carbide substrate, the source material may be a silicon carbide powder, and the single crystal may be a silicon carbide single crystal.

### Details of Embodiments of Present Disclosure

A crucible and a method for producing a single crystal according to an embodiment of the present disclosure will be described below. Production of a silicon carbide single crystal according to an embodiment will be described below. In the embodiments, like parts are denoted by like reference numerals throughout the drawings and will not be described again.

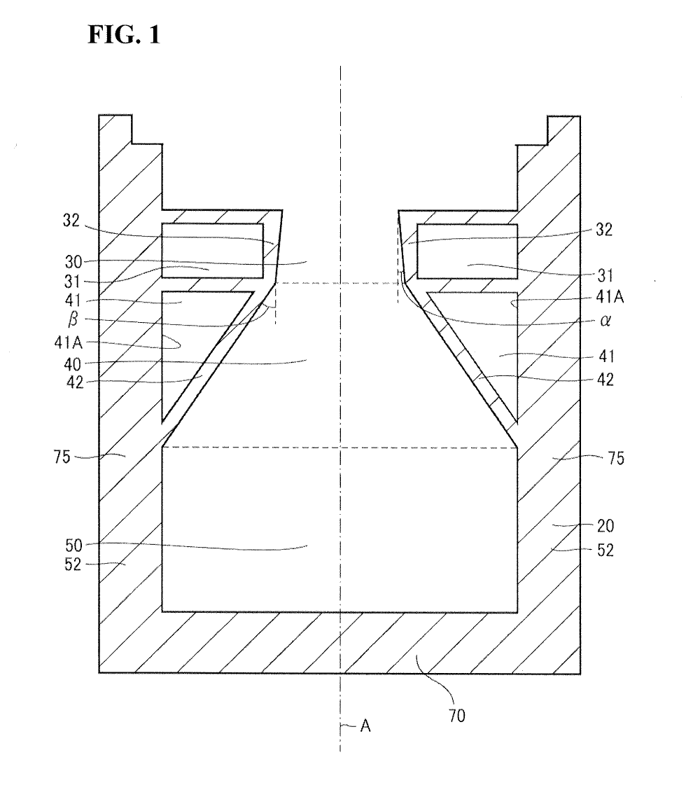

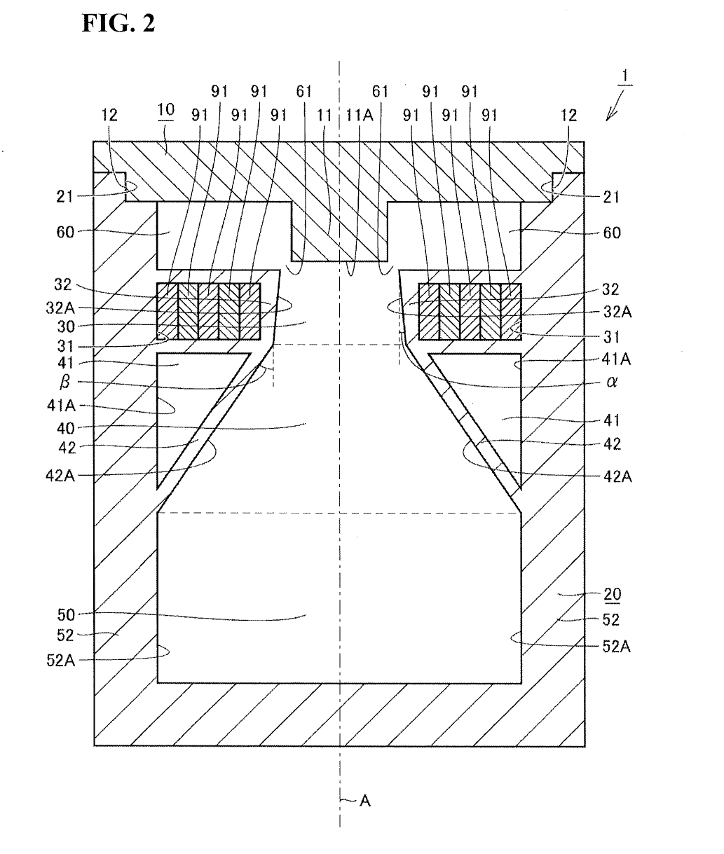

As illustrated in FIGS. 1 and 2, in a crucible 1 according to an embodiment, a source material is sublimated and recrystallizes on a seed crystal. Thus, a single crystal is grown on the seed crystal. The crucible 1 includes a bottom 70 at one end and a cylindrical side surface 75 extending from the bottom 70. The crucible 1 includes a cylindrical main body 20 having an opening at the other end and a disk-shaped lid 10 for covering the opening. The lid 10 and the main body 20 may be made of carbon. More specifically, the lid 10 and the main body 20 may be made of graphite. The lid 10 can be attached to and detached from the main body 20. The lid 10 can be fixed to the main body 20 by bringing a lid contact surface 12, which is part of the outer periphery of the lid 10, into contact with a main body contact surface 21, which is part of the inner periphery of the main body 20. The lid contact surface 12 and the main body contact surface 21 may have a helical thread groove. The lid 10 includes a holding portion 11 protruding from a central portion of a main surface thereof. When the lid 10 is attached to the main body 20, the holding portion 11 is disposed on a central axis A of the cylindrical main body 20. The central axis A is perpendicular to the bottom 70. A single crystal grows along the central axis A. A holding surface 11A for holding a seed crystal is disposed on the tip of the holding portion 11.

The crucible 1 includes a first region 30, which extends from the holding portion 11 in the single crystal growth direction (along the central axis A). The first region 30 is surrounded by a first wall portion 32, which protrudes from an inner circumferential surface of the main body 20 toward the central axis A. The distance between horizontal opposite portions on the first wall portion 32, that is, the distance between horizontal opposite portions on an inner wall surface 32A of the first wall portion 32 increases gradually with distance from the holding portion 11. In other words, the distance between horizontal opposite portions on the first wall portion 32 increases gradually as the horizontal opposite portions approach the bottom 70. From another perspective, the cross-sectional area of the first region 30 perpendicular to the central axis A increases gradually with distance from the holding portion 11. In a cross section including the central axis A, the angle between the inner wall surface 32A of the first wall portion 32 and the single crystal growth direction (the direction of the central axis A) is an inclination angle α (hereinafter also simply referred to as an angle α). In other words, the inclination angle α is the angle between the direction perpendicular to the bottom 70 and the first wall portion 32.

The crucible 1 includes a second region 40, which extends from the first region 30 in the single crystal growth direction (along the central axis A) and in a direction away from the holding portion 11. The second region 40 is surrounded by a second wall portion 42, which protrudes from the inner circumferential surface of the main body 20 toward the central axis A. The distance between horizontal opposite portions on the second wall portion 42 in a direction perpendicular to the central axis A, that is, the distance between horizontal opposite portions on an inner wall surface 42A of the second wall portion 42 increases gradually with distance from the first region 30. In other words, the distance between horizontal opposite portions on the second wall portion 42 increases gradually as the horizontal opposite portions approach the bottom 70. From another perspective, the cross-sectional area of the second region 40 perpendicular to the central axis A increases gradually with distance from the first region 30. In a cross section including the central axis A, the angle between the inner wall surface 42A of the second wall portion 42 and the single crystal growth direction (the direction of the central axis A) is an inclination angle β (hereinafter also simply referred to as an angle β). In other words, the inclination angle β is the angle between the direction perpendicular to the bottom 70 and the second wall portion 42.

The crucible 1 includes a third region 50, which extends from the second region 40 in the single crystal growth direction (along the central axis A) and in a direction away from the first region 30. The third region 50 can hold a raw powder. The third region 50 is surrounded by a third wall portion 52. The distance between horizontal opposite portions on the third wall portion 52, that is, the distance between horizontal opposite portions on an inner wall surface 52A of the third wall portion 52 is constant along the central axis A. In other words, the cross-sectional area of the third region 50 perpendicular to the central axis A is constant along the central axis A. The third wall portion 52 and the second wall portion 42 are entirely joined together with no space therebetween.

The crucible 1 may include a fourth region 60 around the holding portion 11. The fourth region 60 communicates with the first region 30 through a channel space 61.

The first wall portion 32 includes a first chamber 31. The first chamber 31 is a circular space around the first region 30. The first chamber 31 includes a heat insulator 91. The heat insulator 91 may be composed of carbon felt. In the present embodiment, both ends of a belt-like heat insulator 91 are joined, and a plurality of (five in FIG. 2) circular heat insulators 91 are layered. As illustrated in FIG. 2, the first chamber 31 is filled with the heat insulators 91. The heat insulators 91 are stacked in a direction perpendicular to the single crystal growth direction (the direction of the central axis A). A plurality of turns of a belt-like heat insulator 91 may be stacked in a direction perpendicular to the single crystal growth direction (the direction of the central axis A). The first chamber 31 is not necessarily filled with the heat insulator 91. The inner wall of the first chamber 31 and the heat insulator 91 may have a gap therebetween. The first wall portion 32 can be attached to and detached from a side surface 75 of the crucible 1. Such a structure makes the heat insulator 91 easier to place.

The second wall portion 42 includes a second chamber 41. Each region of an inner wall 41A of the second wall portion 42 faces the opposite region of the inner wall 41A with an empty space interposed therebetween. The second chamber 41 is a circular space around the second region 40. The second chamber 41 includes no heat insulator. Thus, the second chamber 41 is empty.

The structure of the crucible 1 according to the embodiment is summarized as described below. The crucible 1 has the bottom 70 and the cylindrical side surface 75. In the crucible 1, a source material is sublimated to grow a single crystal. The crucible 1 includes the third region 50 configured to receive a source material, the second region 40 extending from the third region 50 in a direction away from the bottom 70, and the first region 30 extending from the second region 40 in a direction away from the bottom 70. The first wall portion 32 surrounding the first region 30 and the second wall portion 42 surrounding the second region 40 are disposed inside the side surface 75. The first chamber 31 is disposed between the first wall portion 32 and the side surface 75. The second chamber 41 is disposed between the second wall portion 42 and the side surface 75. The distance between horizontal opposite portions on the first wall portion 32 is constant or increases as the horizontal opposite portions approach the bottom 70. The distance between horizontal opposite portions on the second wall portion 42 increases as the horizontal opposite portions approach the bottom 70. The inclination angle α of the first wall portion 32 with respect to the direction perpendicular to the bottom 70 is smaller than the inclination angle β of the second wall portion 42 with respect to the direction perpendicular to the bottom 70. The inclination angle α is 30 degrees or less. The inclination angle is 70 degrees or less. The difference between the inclination angle β and the inclination angle α is 50 degrees or less. The first chamber 31 includes the heat insulator 91. The second chamber 41 is empty.

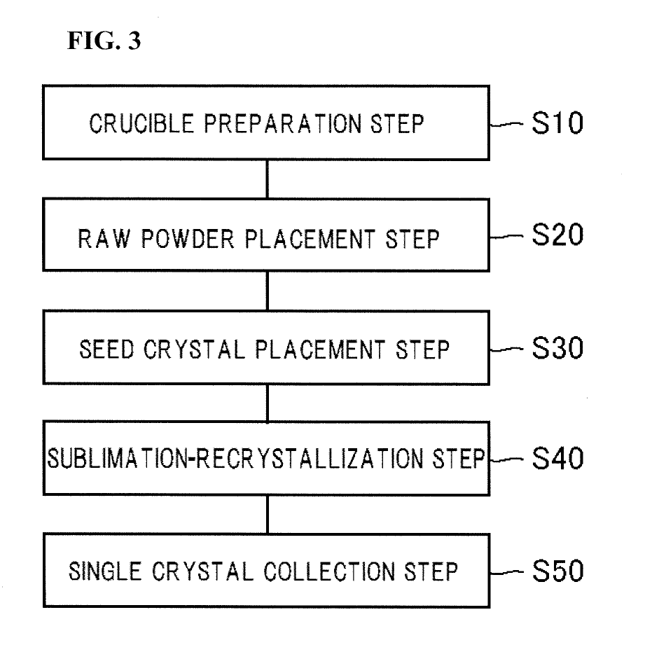

A method for producing a silicon carbide single crystal in the crucible 1 will be described below. As illustrated in FIG. 3, a method for producing a silicon carbide single crystal according to the present embodiment includes steps (S10) to (S50). In the step (S10), a crucible is prepared. The crucible 1 is prepared in the step (S10).

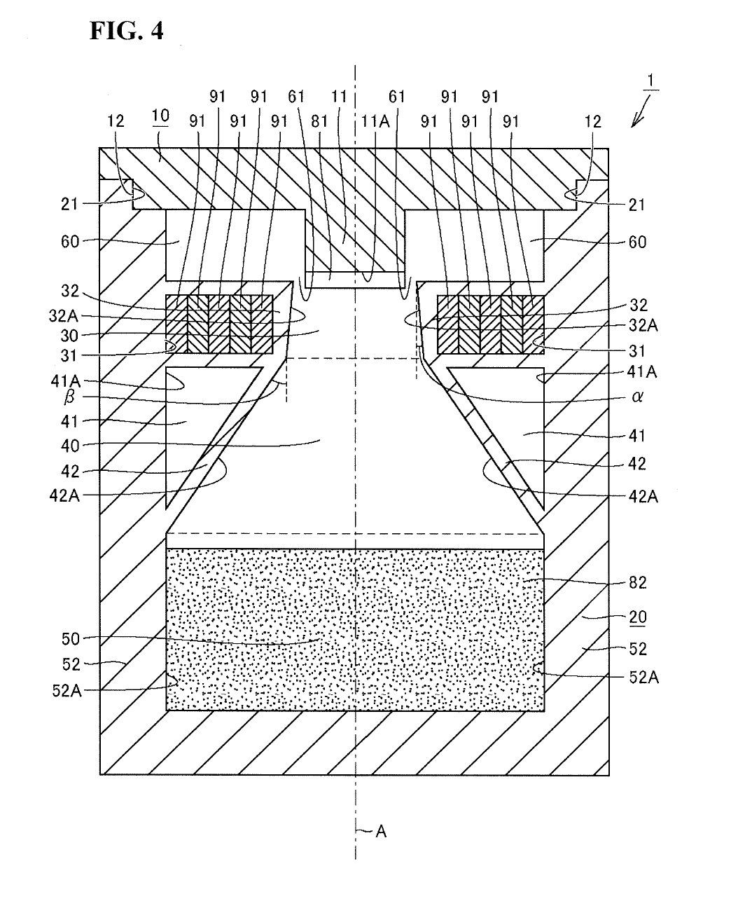

In the step (S20), a raw powder is placed. In the step (S20), as illustrated in FIG. 4, a raw powder 82 is placed as a source material in the third region 50 of the crucible 1. The raw powder 82 is a silicon carbide powder. More specifically, while the lid 10 is removed, the raw powder 82 is placed in the main body 20.

In the step (S30), a seed crystal is placed. In the step (S30), a seed crystal 81 is placed on the holding portion 11. More specifically, for example, the seed crystal 81 is fixed to the holding portion 11 of the lid 10 removed from the main body 20. The lid 10 is then attached to the main body 20. Thus, the seed crystal 81 is disposed in a region crossing the central axis A of the crucible 1. Through the steps (S10) to (S30), the raw powder 82 and the seed crystal 81 are placed in the crucible 1.

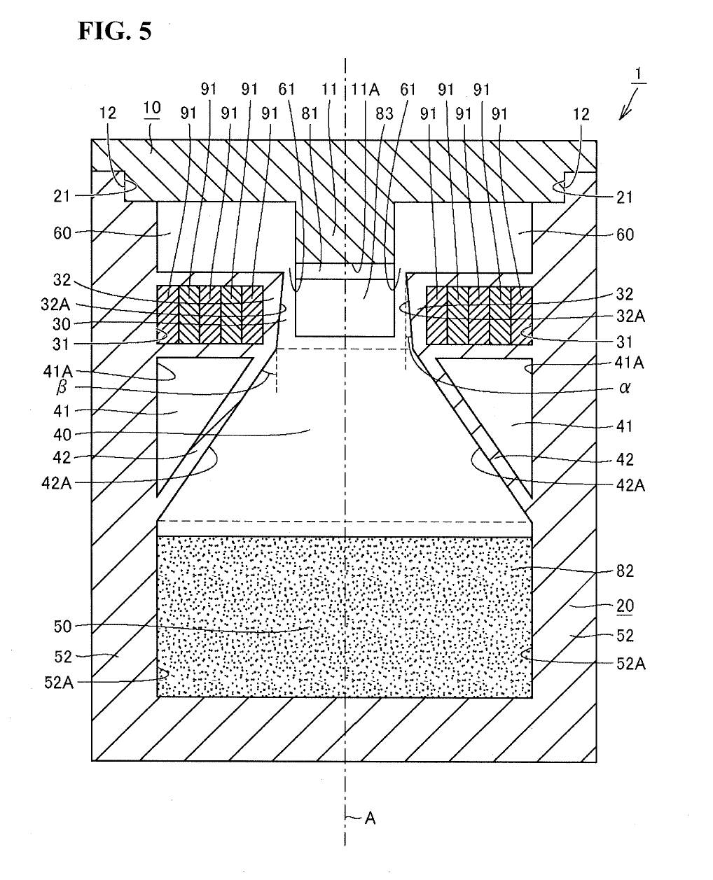

The step (S40) includes sublimation-recrystallization. In the step (S40), the raw powder 82 is sublimated and recrystallizes on the seed crystal 81. More specifically, for example, the crucible 1 including the raw powder 82 and the seed crystal 81 is placed in a furnace equipped with an induction heating apparatus (not shown). The crucible 1 is heated in the furnace. As illustrated in FIG. 5, the raw powder 82 is sublimed to generate a silicon carbide source material gas. The source material gas reaches the first region 30 through the third region 50 and the second region 40 while being concentrated around the central axis A. This is because the distance between horizontal opposite portions on the second wall portion 42, that is, the distance between horizontal opposite portions on the inner wall surface 42A of the second wall portion 42 decreases gradually from the third region 50 to the first region 30.

The source material gas reaching the first region 30 is supplied to the seed crystal 81. The source material gas recrystallizes on the seed crystal 81. Thus, the silicon carbide single crystal 83 is formed on the seed crystal 81. As the raw powder is continuously sublimed, the single crystal 83 grows along the central axis A. Thus, the single crystal 83 grows toward the bottom 70. Heating is stopped after a predetermined heating time. Thus, the step (S40) is completed.

In the step (S50), the single crystal is collected. In the step (S50), the single crystal grown in the crucible 1 in the step (S40) is removed from the crucible 1. More specifically, after heating in the step (S40), the crucible 1 is removed from the furnace. The lid 10 of the crucible 1 is then removed from the main body 20. The single crystal 83 is collected from the lid 10. More specifically, for example, the single crystal 83 is cut near a boundary line between the single crystal 83 and the seed crystal 81. The single crystal is produced through these steps. The single crystal can be sliced into a plurality of silicon carbide substrates. The silicon carbide substrates can be used to manufacture semiconductor devices.

As described above, the first chamber 31 of the crucible 1 according to the embodiment includes the heat insulator 91. The heat insulator 91 decreases the thermal conductivity of the first chamber 31. Radiation has a great influence in a temperature range up to 2000° C., for example. The heat insulator 91 in the first chamber 31 can block radiation. The heat insulator 91 reduces heat transfer in the first chamber 31. Thus, the heat insulator 91 reduces the effects of radiant heat from the first chamber 31 to the first region 30. This can decrease the temperature difference in a direction perpendicular to the central axis A (a radial direction of the single crystal 83) in the first region 30. This can reduce the difference in thickness between a radial end portion and a central portion of the single crystal 83 during growth (for example, 3 mm or less). Thus, the single crystal 83 has decreased strain and a decreased number of defects.

The second wall portion 42 of the crucible 1 includes a second chamber 41. Each region of an inner wall 41A of the second wall portion 42 faces the opposite region of the inner wall 41A with an empty space interposed therebetween. The second wall portion 42 of the crucible 1 includes an empty second chamber 41, which does not include the heat insulator 91. Radiation has a great influence in a temperature range up to 2000° C., for example. The empty second chamber 41 does not block radiation. Thus, heat is easily transferred in the second chamber 41. This increases radiant heat from the second wall portion 42 to the raw powder 82 in the vicinity of the central portion of the interior space of the crucible 1 (around the central axis A). This suppresses a decrease in temperature in the vicinity of the central portion. Thus, the formation of crystalline mass due to recrystallization is suppressed in the vicinity of the central portion.

In the crucible 1, the third wall portion 52 and the second wall portion 42 are joined together with no space therebetween. Thus, the source material gas generated in the third region 50 can be supplied to the first region 30 through the second region 40 without significant loss. This can suppress the decrease in the growth rate of the single crystal 83.

The heat insulators 91 are stacked in a direction perpendicular to the growth direction of the single crystal 83 (the direction of the central axis A). In other words, the heat insulators 91 are stacked in the radial direction of the crucible 1. Thus, the heat insulators 91 can improve heat-insulating properties in the direction perpendicular to the central axis A. This reduces the temperature difference in a radial direction of the single crystal 83 (in a direction perpendicular to the central axis A) in the first region 30. This can reduce the difference in thickness between a radial end portion and a central portion of the single crystal 83 during growth. Thus, the single crystal 83 thus grown is of high quality with decreased strain and a decreased number of defects.

The crucible 1 may include a fourth region 60. Part of the source material gas that did not contribute to normal growth of the single crystal 83 flows into the fourth region 60 through a channel 61. The source material gas in the fourth region 60 recrystallizes in the fourth region 60. This can prevent part of the source material gas that did not contribute to normal growth of the single crystal 83 from recrystallizing on a side surface of the single crystal 83 to form a polycrystal on the single crystal 83. Thus, the single crystal 83 thus grown has improved quality.

As described above, the crucible 1 according to the embodiment can be used to produce the single crystal 83 having a decreased number of defects without a significant decrease in growth rate.

The inclination angle α may be 5 degrees or less. The angle α may be 0 degrees. In other words, the distance between horizontal opposite portions on the first wall portion 32 may be constant. This can suppress the increase in the diameter of a single crystal resulting from single crystal growth. This can decrease the accumulation of strain in the single crystal resulting from single crystal growth and decrease the number of defects and cracks.

The angle β may be 20 degrees or more. This allows the source material gas to be supplied to the first region 30 from a wider area. This can further suppress the decrease in the growth rate of the single crystal 83.

In a method for producing a single crystal according to the present embodiment, the growth of the single crystal 83 in the step (S40) for growing the single crystal 83 is preferably limited to the first region 30. The temperature difference of the single crystal 83 in the radial direction can be decreased in the first region 30. Thus, strain in the single crystal 83 can be decreased by limiting the growth of the single crystal 83 in the first region 30. As a result, the single crystal 83 thus produced has improved quality.

### First Modified Example

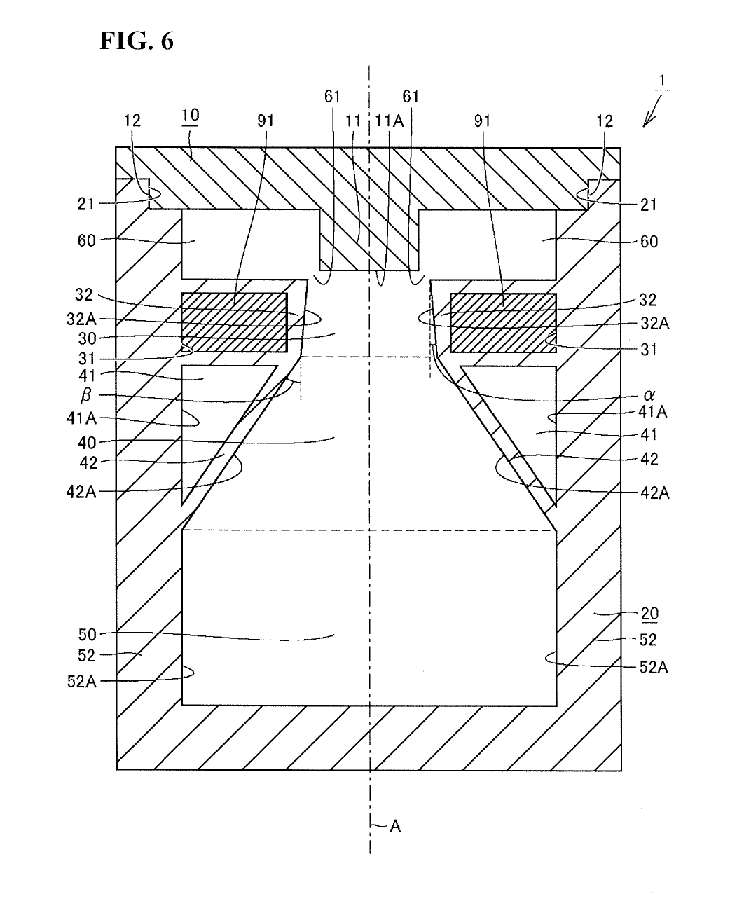

As illustrated in FIG. 6, the crucible 1 according to the embodiment and a crucible 1 according to a first modified example are different in the structure of a heat insulator. More specifically, in the crucible 1 according to the first modified example, the first chamber 31 includes a single heat insulator 91. The crucible 1 according to the first modified example can also be used to produce a single crystal having a decreased number of defects without a significant decrease in growth rate. Also in the first modified example, the inner wall of the first chamber 31 and the heat insulator 91 may have a gap therebetween. The crucible 1 according to the first modified example can be used to produce a silicon carbide single crystal.

### Second Modified Example

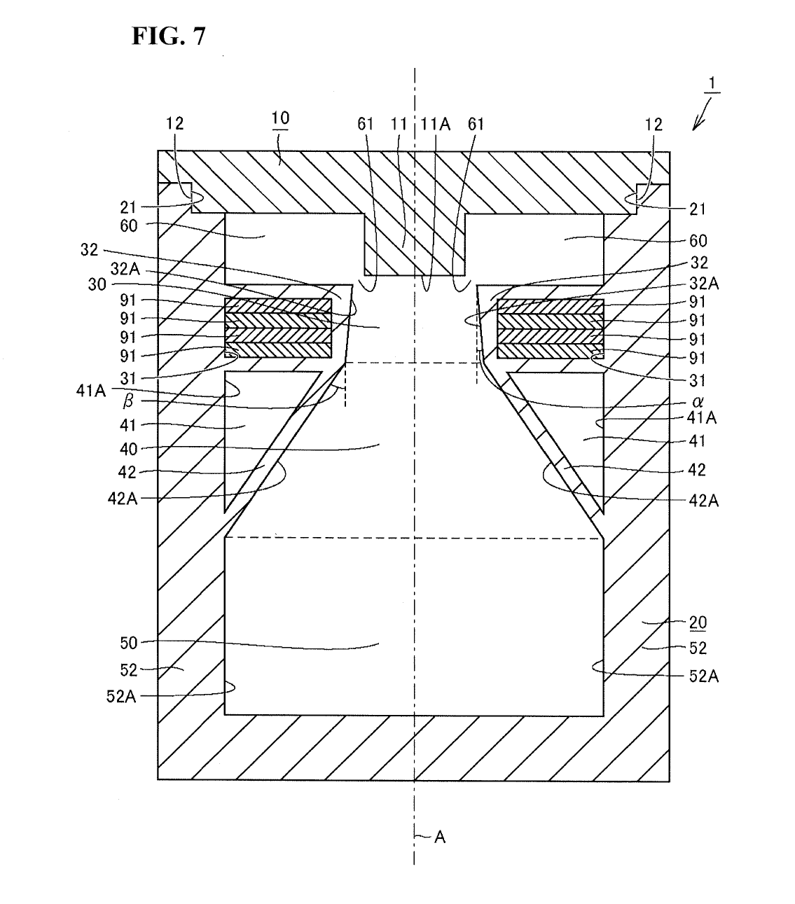

As illustrated in FIG. 7, the crucible 1 according to the embodiment and a crucible 1 according to a second modified example are different in the structure of a heat insulator. More specifically, in the crucible 1 according to the second modified example, heat insulators 91 in the first chamber 31 are stacked in the single crystal growth direction (in the direction of the central axis A). In other words, a plurality of heat insulators 91 are stacked in a direction perpendicular to the bottom 70. The crucible 1 according to the second modified example can also be used to produce a single crystal having a decreased number of defects without a significant decrease in growth rate. Also in the second modified example, the inner wall of the first chamber 31 and the heat insulator 91 may have a gap therebetween. The crucible 1 according to the second modified example can be used to produce a silicon carbide single crystal.

Production of a silicon carbide single crystal has been described with the embodiments. A crucible and a method for producing a single crystal according to the present disclosure can be used to produce another single crystal that can be produced by a sublimation method, for example, an aluminum nitride single crystal.

### [Evaluation]

The quality and growth rate of a single crystal are evaluated in the production of a silicon carbide single crystal. The evaluation procedures are described below.

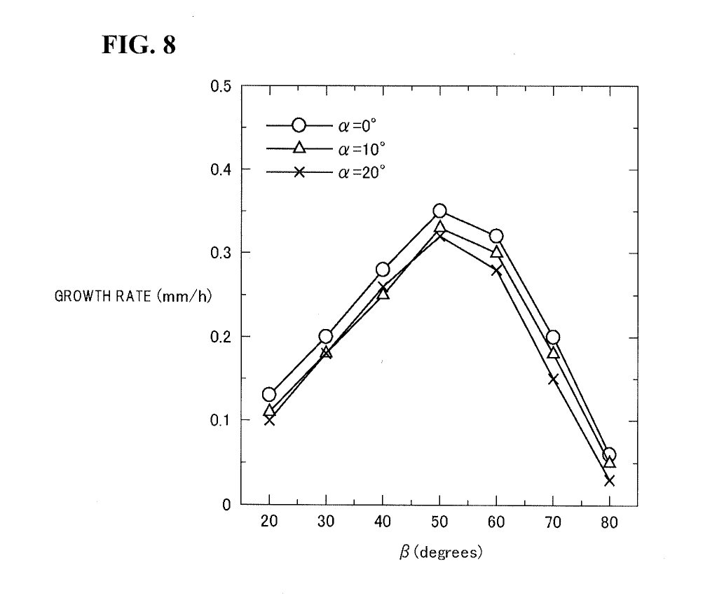

A crucible having the structure of the crucible 1 according to the embodiment was used. The angle α ranged from 0 to 40 degrees, and the angle β ranged from 20 to 80 degrees. A single crystal was grown in accordance with the procedures described in the embodiment. Evaluation items were cracking in the single crystal, deposition of a polycrystal on a joint between the first region 30 and the second region 40, formation of crystalline mass on the raw powder 82, and the growth rate of the single crystal 83. Table and FIG. 8 show the evaluation items. In FIG. 8, the horizontal axis represents the angle β. The vertical axis represents the single crystal growth rate (the increase in the thickness of a single crystal per hour in the single crystal growth direction).

TABLE

| α | β | β − α | | Deposi- | Formation | Growth |
|---|---|---|---|---|---|---|
| (de- | (de- | (de- | | tion of | of crystal- | rate |
| gree) | gree) | gree) | Cracking | polycrystal | line mass | (mm/h) |
| 0 | 20 | 20 | None | None | None | 0.13 |
| 0 | 30 | 30 | None | None | None | 0.2 |
| 0 | 40 | 40 | None | None | None | 0.28 |
| 0 | 50 | 50 | None | Slight | None | 0.35 |
| 0 | 60 | 60 | None | Observed | None | 0.32 |
| 0 | 70 | 70 | None | Observed | Slight | 0.2 |
| 0 | 80 | 80 | None | Observed | Observed | 0.06 |
| 10 | 20 | 10 | None | None | None | 0.11 |
| 10 | 30 | 20 | None | None | None | 0.18 |
| 10 | 40 | 30 | None | None | None | 0.25 |
| 10 | 50 | 40 | None | None | None | 0.33 |
| 10 | 60 | 50 | None | Slight | None | 0.3 |
| 10 | 70 | 60 | None | Observed | Slight | 0.18 |
| 10 | 80 | 70 | None | Observed | Observed | 0.05 |
| 20 | 20 | 0 | None | None | None | 0.1 |
| 20 | 30 | 10 | None | None | None | 0.18 |
| 20 | 40 | 20 | None | None | None | 0.26 |
| 20 | 50 | 30 | None | None | None | 0.32 |
| 20 | 60 | 40 | None | None | None | 0.28 |
| 20 | 70 | 50 | None | Slight | Slight | 0.15 |
| 20 | 80 | 60 | None | Observed | Observed | 0.03 |
| 30 | 50 | 20 | Slight | None | None | 0.3 |
| 40 | 60 | 20 | Observed | None | None | 0.25 |

Table shows that cracking in the single crystal occurred at a high angle α. No or few cracks were observed at an angle α of 30 degrees or less. Thus, the angle α is preferably 30 degrees or less. No crack was observed at an angle α of 20 degrees or less. Thus, the angle α is more preferably 20 degrees or less. In order to decrease cracks in the single crystal, the angle α is preferably as low as possible. Thus, in order to decrease cracks, the angle α is still more preferably 5 degrees or less, still more preferably 0 degrees.

Deposition of a polycrystal on a joint between the first region 30 and the second region 40 was observed when the difference between the angle β and the angle α (β−α) was more than 50 degrees. Thus, the difference between the angle β and the angle α is preferably 50 degrees or less. No deposition of a polycrystal was observed when the difference between the angle β and the angle α was 40 degrees or less. Thus, the difference between the angle β and the angle α is more preferably 40 degrees or less.

Formation of crystalline mass on the raw powder 82 was observed at a high angle β. Formation of crystalline mass can be significantly reduced at an angle β of 70 degrees or less. Thus, the angle β is preferably 70 degrees or less. Formation of crystalline mass was not observed at an angle β of 60 degrees or less. Thus, the angle β is more preferably 60 degrees or less, still more preferably 50 degrees or less.

Table and FIG. 8 show that the angle β has an appropriate range in terms of the single crystal growth rate. The plausible reason for this is as follows: As described above, a high angle β results in the formation of crystalline mass and a low growth rate. Thus, as described above, the angle β is preferably 70 degrees or less, more preferably 60 degrees or less. However, at an excessively low angle β, it is difficult to supply the source material gas to the first region 30 from a wide area. This results in a low single crystal growth rate. In order to increase the growth rate, the angle β is preferably 20 degrees or more, more preferably 30 degrees or more. An angle β of 40 degrees or more can further increase the growth rate.

Although not shown in Table and FIG. 8, defects resulting from strain in a single crystal were decreased in all the single crystals.

It is to be understood that the embodiments and examples disclosed herein are illustrated by way of example and not by way of limitation in all respects. The scope of the present invention is defined by the appended claims rather than by the description preceding them. All modifications that fall within the scope of the claims and the equivalents thereof are therefore intended to be embraced by the claims.

What is claimed is:

1. A crucible for sublimating a source material to grow a single crystal, comprising:
a bottom; and
a cylindrical side surface,
wherein the crucible includes a third region configured to receive the source material
a second region extending from the third region in a direction away from the bottom, and
a first region extending from the second region in a direction away from the bottom,
the crucible includes a first wall and a second wall inside the side surface, the first wall surrounding the first region, the second wall surrounding the second region,
the crucible includes a first chamber between the first wall and the side surface and a second chamber between the second wall and the side surface,
a distance between horizontal opposite portions on the first wall is constant or increases as the horizontal opposite portions approach the bottom, and a distance between horizontal opposite portions on the second wall increases as the horizontal opposite portions approach the bottom,
an inclination angle α of the first wall with respect to a direction perpendicular to the bottom is smaller than an inclination angle β of the second wall with respect to a direction perpendicular to the bottom, the inclination angle α is 30 degrees or less, the inclination angle β is 70 degrees or less, and a difference between the inclination angle β and the inclination angle α is 50 degrees or less, and
the first chamber includes a heat insulator, and the second chamber is empty.

2. The crucible according to claim 1, wherein the inclination angle α is 5 degrees or less.

3. The crucible according to claim 1, wherein the inclination angle β is 20 degrees or more.

4. The crucible according to claim 1, wherein the inclination angle α is 5 degrees or less, and the inclination angle β ranges from 20 to 50 degrees.

5. The crucible according to claim 1, wherein the first chamber includes a single heat insulator.

6. The crucible according to claim 1, wherein the first chamber includes radially stacked heat insulators.

7. The crucible according to claim 1, wherein the first chamber includes a plurality of heat insulators stacked in a direction perpendicular to the bottom.

8. The crucible according to claim 1, further comprising a lid portion for covering an opening of the crucible, wherein the lid portion has a holding portion for holding a seed crystal on a surface thereof facing the bottom.

9. A crucible for sublimating a source material to grow a single crystal, comprising:
a bottom; and
a cylindrical side surface,
wherein the crucible includes a third region configured to receive the source material,
a second region extending from the third region in a direction away from the bottom, and
a first region extending from the second region in a direction away from the bottom,
the crucible includes a first wall and a second wall inside the side surface, the first wall surrounding the first region, the second wall surrounding the second region,
the crucible includes a first chamber between the first wall and the side surface and a second chamber between the second wall and the side surface,
a distance between horizontal opposite portions on the first wall is constant or increases as the horizontal opposite portions approach the bottom, and a distance between horizontal opposite portions on the second wall increases as the horizontal opposite portions approach the bottom,
an inclination angle α of the first wall with respect to a direction perpendicular to the bottom is 5 degrees or less, and an inclination angle β of the second wall with respect to a direction perpendicular to the bottom ranges from 20 to 50 degrees, and
the first chamber includes a plurality of radially stacked heat insulators, and the second chamber is empty.

10. A method for producing a single crystal using the crucible according to claim 8, comprising:
placing a source material in at least part of the third region;
placing a seed crystal on the holding portion;
sublimating the source material to grow the single crystal on the seed crystal; and
separating the single crystal from the seed crystal.

11. The method for producing a single crystal according to claim 10, wherein
the placing of a seed crystal on the holding portion includes placing the seed crystal in the first region, and
the sublimating of the source material to grow the single crystal on the seed crystal includes limiting the single crystal growth in the first region.

12. The method for producing a single crystal according to claim 11, wherein the seed crystal is a silicon carbide substrate, the source material is a silicon carbide powder, and the single crystal is a silicon carbide single crystal.
